(19) United States
(12) Patent Application Publication
(10) Pub. No.: US 2019/0229282 A1
(43) Pub. Date: Jul. 25, 2019

(54) FLEXIBLE OLED DISPLAY PANEL AND MANUFACTURING METHOD THEREOF, DISPLAY DEVICE

(71) Applicant: Wuhan China Star Optoelectronics Semiconductor Display Technology Co., Ltd., Wuhan, Hubei (CN)

(72) Inventors: Ming ZHANG, Wuhan, Hubei (CN); HSIANG LUN HSU, Wuhan, Hubei (CN)

(21) Appl. No.: 15/579,454

(22) PCT Filed: Nov. 28, 2017
(86) PCT No.: PCT/CN2017/113248

§ 371 Date: Dec. 4, 2017

(30) Foreign Application Priority Data
Nov. 21, 2017 (CN) 201711163470.X

(51) Int. Cl. H01L 51/00; H01L 27/32; H01L 51/56

(52) U.S. Cl. CPC H01L 51/0097; H01L 51/56; H01L 51/003; H01L 27/3244

(57) ABSTRACT

A flexible OLED display panel is provided. The flexible OLED display panel includes flexible substrate and OLED display unit formed on flexible substrate. The flexible substrate includes first surface and second surface corresponding to first surface, OLED display unit is formed on second surface, a plurality of patterning recesses is formed on first surface of flexible substrate f. The method of manufacture flexible OLED display panel comprising following steps: providing a rigid substrate and forming an inorganic thin film layer thereon; etching a plurality of patterning projections on the inorganic thin film layer; forming a flexible substrate on the inorganic thin film layer; processing an OLED display unit on a second surface; separating the flexible substrate form the rigid substrate and the inorganic thin film layer by laser lift-off process and obtaining the flexible OLED display panel. The invention discloses the display device includes the flexible OLED display panel.

### RELATED APPLICATIONS

The present application is a National Phase of International Application Number PCT/CN2017/113248, filed Nov. 28, 2017, and claims the priority of China Application No. 201711163470.X, filed Nov. 21, 2017.

### FIELD OF THE DISCLOSURE

The disclosure relates to a display technical field, and more particularly to a flexible OLED display panel and manufacturing method thereof, further by a display device has a flexible OLED display panel.

### BACKGROUND

An Organic Light-Emitting Diode (OLED) plays a vital role in the field of next-generation flat display applications due to its advantages of self-emitting, a high display contrast, a low thickness, a wide angle of view, a high response speed and availability to a flexible panel, etc. The flexible OLED display panel is one of the most important development trends.

The flexible display panel not only provides thinner size, but also decreases power consumption and enhances endurance of relative products. At the same time, because the flexible OLED display panel could be curved and bended, the durability also better than other rigid display panel. The flexible OLED display panel could be widely applied to other products which has display function, for example a panel, a television, a mobile terminal and wearable apparatus.

Usually, the flexible OLED display panel includes a flexible substrate and an OLED display unit formed on the flexible substrate. The OLED display unit comprises a TFT array layer, an anode layer, an organic light-emitting layer, a cathode layer and a packaged layer are formed on the flexible substrate sequentially. When the flexible OLED display panel is curved, the stress will happened, specifically, the stretch stress is happened to the convex outer surface and press stress is happened to the concave inner surface. In order to avoid the abnormal display image, usually positioned the organic-light emitting layer of the OLED display unit on the neutral surface which does not existing stress (or less stress). At this time, the flexible substrate is positioned away the neutral surface. When the flexible OLED display panel is curving, the stress of the flexible substrate is greater, and the problem to be solved which is how to decrease stress of the flexible substrate.

### SUMMARY

A technical problem to be solved by the disclosure is to provide a flexible OLED display panel and manufacturing method thereof with reduced stress of flexible substrate when the flexible OLED display panel is been curved.

An objective of the disclosure is achieved by following embodiments.

In particular, a flexible OLED display panel includes a flexible substrate and an OLED display unit formed on the flexible substrate. The flexible substrate includes a first surface and a second surface corresponding to the first surface, the OLED display unit is formed on the second surface, a plurality of patterning recesses is formed on the first surface of the flexible substrate.

In an embodiment, longitudinal section of the recess is rectangular shape, trapezoid shape or counter trapezoid shape.

In an embodiment, depth of the recess is equal to or smaller than half of thickness of the flexible substrate.

In an embodiment, a plurality of patterning recesses is arranged on the first surface in array.

In an embodiment, the OLED display unit comprises a TFT array layer, an anode layer, an organic light-emitting layer, a cathode layer and a packaged layer are formed on the second surface sequentially.

According to another aspect of the disclosure, the disclosure further provides a method of manufacture flexible OLED display panel. The method of manufacture flexible OLED display panel comprises following steps:

providing a rigid substrate and forming an inorganic thin film layer on the rigid substrate;

etching a plurality of patterning projections on the inorganic thin film layer by photolithography process;

forming a flexible substrate on the inorganic thin film layer by coating process, and mating the plurality of patterning projections and a first surface of the flexible substrate which is positioned toward the inorganic thin film layer;

processing an OLED display unit on a second surface which is corresponding to the first surface of the flexible substrate; and

separating the flexible substrate form the rigid substrate and the inorganic thin film layer by laser lift-off process; wherein the first surface of the flexible substrate is formed a plurality of patterning recesses which corresponding to the plurality of patterning projections.

According to another aspect of the disclosure, the disclosure further yet provides a display device. The display device comprising a driver unit and a flexible OLED display panel, the driver unit provides driver signal to the flexible OLED display panel for displaying image on the flexible OLED display panel.

The flexible OLED display panel and display device of the embodiment in this invention, a plurality of patterning recesses are formed on the surface which positioned away the OLED display unit. When the flexible OLED display panel is curving; the plurality of patterning recesses could release the stretch or compression stress generated by the flexible substrate so that enhances bending property of flexible OLED display panel. The manufacture is simplified and easily to achieved.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural schematic view of a flexible OLED display panel according to an embodiment of the disclosure;

FIG. 2 is a planar structural schematic view of a first surface of flexible substrate according to an embodiment of the disclosure;

FIG. 3 is an enlarge schematic view of A portion shown in the FIG. 1;

FIG. 4 is a structural schematic view of a flexible substrate according to another embodiment of the disclosure;

FIG. 5 is a structural schematic view of a flexible substrate according to another embodiment of the disclosure;

FIG. 6a-6e are a method of manufacture the flexible OLED display panel, and illustrates device structure obtained by each corresponding steps according to an embodiment of the disclosure; and

FIG. 7 is a structural schematic view of display device according to an embodiment of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

Here, it is also worthy to note that, in order to prevent the present disclosure from being obscured due to unnecessary details, the drawings only illustrate the structure and/or processing steps closely related to the technical solution of the present disclosure, while other details less related to the present disclosure are omitted.

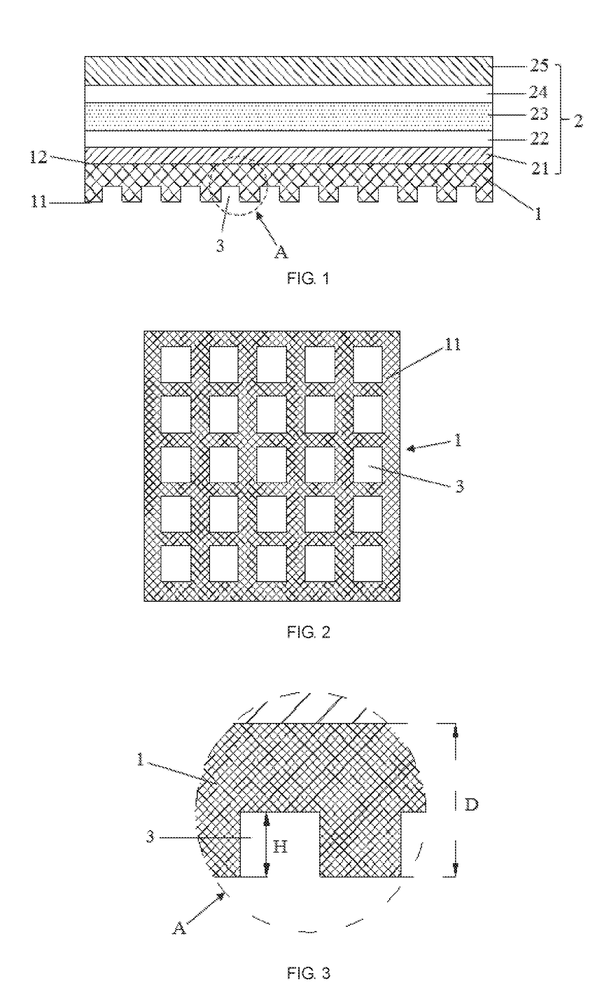

The flexible OLED display panel of this embodiment, please refer to FIG. 1. The flexible OLED display panel comprises a flexible substrate 1 and an OLED display unit 2 formed on the flexible substrate 1. Wherein, the flexible substrate 1 includes a first surface 11 and a second surface 12 corresponding to the first surface 11, the OLED display unit 2 is formed on the second surface 12, a plurality of patterning recesses 3 is formed on the first surface 11 of the flexible substrate 1. When the flexible OLED display panel is curving, the plurality of patterning recesses 3 could releases the stretch or compression stress generated by the flexible substrate 1 so that enhances bending property of flexible OLED display panel.

Wherein, please refer to FIG. 1 and FIG. 2. In this embodiment, longitudinal section of the recess 3 is rectangular shape, and the plurality of recesses 3 is arranged on the first surface 11 of the flexible substrate 1 in array.

It is noted that, open shape and size of the recesses 3 in the planar do not need special design, it because gap portion of the recesses 3 could releases stress generated by the flexible substrate 1. Of course, it better to design some regular shape. The recesses 3 also could be irregular array on the first surface 11 of the flexible substrate 1, but it need more uniform distribution on each region of the first surface 11. Further, depth of the recesses 3 could be design according to the needs. In preferably embodiment, depth H of the recesses 3 is equal to or smaller than thickness D of the substrate 1, which is H≤D/2

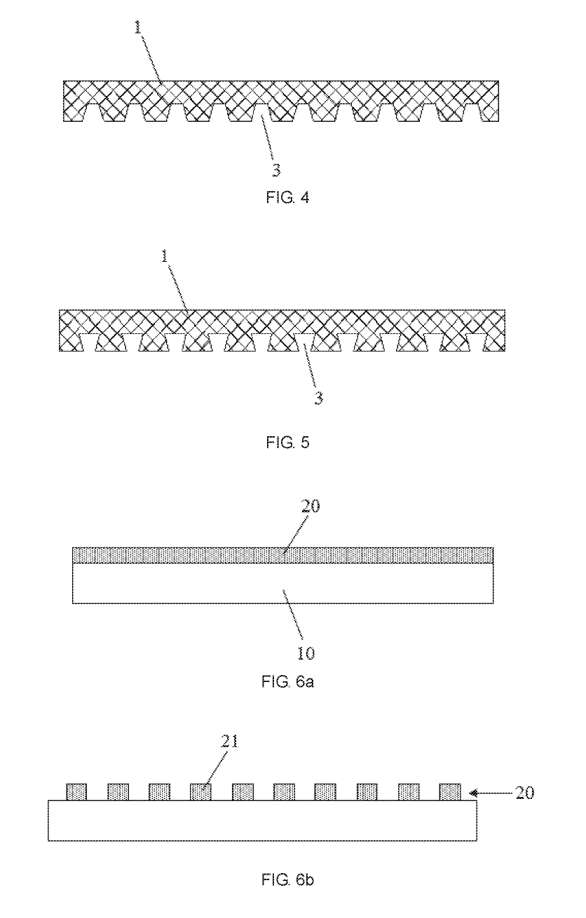

Further, please refer to FIG. 4 and FIG. 5. According to the experiment, when longitudinal section of the recess 3 is trapezoid shape (shown as FIG. 4) or counter trapezoid shape (shown as FIG. 5), the correspondingly flexible substrate 1 will has better property for releasing stress.

Wherein, the flexible substrate 1 could made by polymer material of polyimide (PI)⋅polycarbonate (PC) polyethersulfone (PES)⋅polyethylene terephthalate (PET)⋅polyethylene naphthalate) (PEN)⋅polyarylate (PAR) or fiber-reinforced plastic (FRP).

Wherein, please refer to FIG. 1. The OLED display unit 2 comprises a TFT array layer 21, an anode layer 22, an organic light-emitting layer 23, a cathode layer 24 and a packaged layer 25 are formed on the second surface 12 of the flexible substrate 1 sequentially. Wherein, the TFT array layer 21 has a TFT, a data line and a scan line and some structure layers. Wherein, the organic light-emitting layer 23 further includes a Hole Transport Layer (HTL), an Emissive Layer (EML) and an Electron Transport Layer (ETL) and so on which are made by organic material.

Further, the packaged layer 25 has a touch panel, polarizer, protect cover and some functional structure layers.

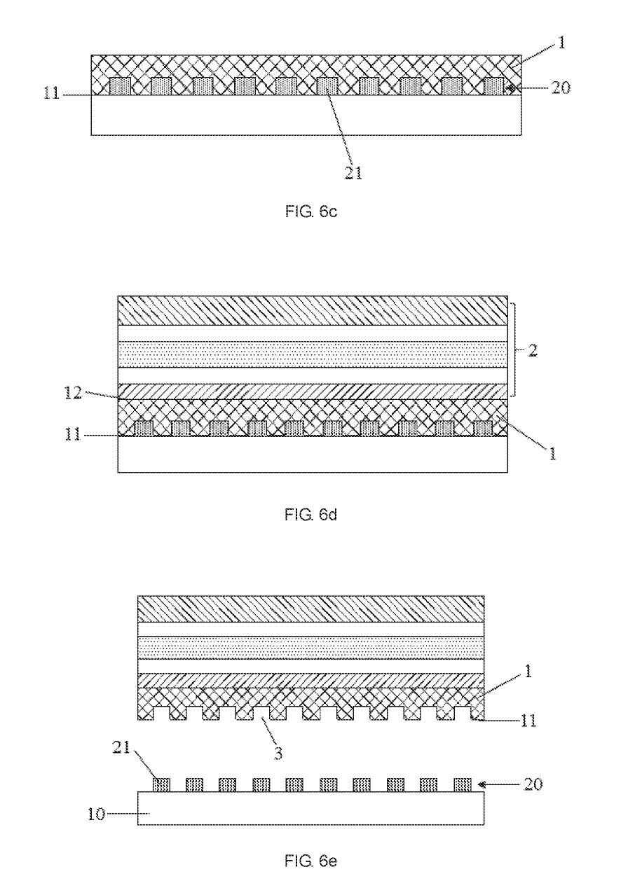

Please refer to FIGS. 6a to 6e, here will introduces a method of manufacture the flexible OLED display panel described above, comprising following steps.

S101, please refer to 6a. Providing a rigid substrate 10 and forming an inorganic thin film layer 20 on the rigid substrate 10. The rigid substrate 10 which is for example a glass substrate. The inorganic thin film layer 20 which is for example a SiNx material layer or SiOx material layer.

S102, please refer to 6b. Etching a plurality of patterning projections 21 on the inorganic thin film layer 20 by photolithography process. The plurality of projections 21 is corresponding to the recesses formed on the flexible substrate by the following step. Hence, shape and size of plurality of patterning projections 21 are designed by shape and size of the recesses.

S103, please refer to 6c. Forming a flexible substrate 1 on the inorganic thin film layer 20 by coating process, and the plurality of patterning projections 21 are mating to a first surface 11 of the flexible substrate 1 which is positioned toward the inorganic thin film layer 20. Which is, thickness of the flexible substrate 1 is greater than height of the plurality of patterning projections 21, the flexible substrate 1 is totally covered the projections 21 and filled between two adjacent projections 21.

S104, please refer to 6d. Processing an OLED display unit 2 on a second surface 12 which is corresponding to the first surface 11 of the flexible substrate 1. Specifically, sequentially processing each functional layers of the OLED display unit 2 on the second surface 12 of the flexible substrate 1. The specifically process will be choosing for any kind processes in this field.

S105, please refer to 6e. Separating the flexible substrate 1 form the rigid substrate 10 and the inorganic thin film layer 20 by laser lift-off (110) process, and obtaining the flexible OLED display panel. Wherein, forming a plurality of patterning recesses 3 on the first surface 11 of the flexible substrate 1, and the plurality of patterning recesses 3 are corresponding to the plurality of patterning projections 21.

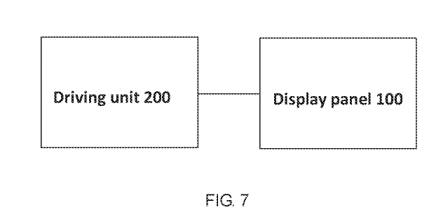

A display device of this embodiment, please refer to FIG. 7. The display device comprising a driver unit 200 and an OLED display panel 100. The driver unit 200 provides driver signal to the OLED display panel 100 for displaying image on the OLED display panel 100. The OLED display panel is the flexible OLED display panel described above.

In sum, the flexible OLED display panel and display device of the embodiment in this invention, a plurality of patterning recesses are formed on the surface which positioned away the OLED display unit. When the flexible OLED display panel is curving, the plurality of patterning recesses could release the stretch or compression stress generated by the flexible substrate so that enhances bending property of flexible OLED display panel. The manufacture is simplified and easily to achieved.

It should be explained that the relationship terms, such as first and second, etc., in the present application are only used for distinguishing one entity or operation from another entity or operation without requiring or implying any actual relation or sequence existing between these entities or operations. Moreover, the term “include”, “contain” or any other variant means covering instead of exclusively including, so that the process, method, object or device including a series of factors not only includes those factors, but also includes other factors that are not explicitly listed, or further include inherent factors for this process, method, object or device. In a case of no more limitations being provided, the factors defined by the expression “include one . . . ” do not exclude additional identical factors existing in the process, method, object or device which includes the factors.

The above statements are only the specific embodiments of the present application. It should be pointed out that improvements and modification can be made by those ordinary skilled in the art without breaking away from the principle of the present application, also those improvements and modification should be considered as the protection scope of the present application.

What is claimed is:

1. A flexible OLED display panel, comprising
a flexible substrate, and
an OLED display unit formed on the flexible substrate;
wherein the flexible substrate includes a first surface and a second surface corresponding to the first surface, the OLED display unit is formed on the second surface, a plurality of patterning recesses is formed on the first surface of the flexible substrate.

2. The flexible OLED display panel according to claim 1, wherein longitudinal section of the recess is rectangular shape.

3. The flexible OLED display panel according to claim 1, wherein longitudinal section of the recess is trapezoid shape or counter trapezoid shape.

4. The flexible OLED display panel according to claim 1, wherein depth of the recess is equal to or smaller than half of thickness of the flexible substrate.

5. The flexible OLED display panel according to claim 1, wherein a plurality of patterning recesses is arranged on the first surface in array.

6. The flexible OLED display panel according to claim 1, wherein the OLED display unit comprises a TFT array layer, an anode layer, an organic light-emitting layer, a cathode layer and a packaged layer are formed on the second surface sequentially.

7. A method of manufacture flexible OLED display panel, comprising steps:
providing a rigid substrate and forming an inorganic thin film layer on the rigid substrate;
etching a plurality of patterning projections on the inorganic thin film layer by photolithography process;
forming a flexible substrate on the inorganic thin film layer by coating process, and mating the plurality of patterning projections and a first surface of the flexible substrate which is positioned toward the inorganic thin film layer;
processing an OLED display unit on a second surface which is corresponding to the first surface of the flexible substrate; and
separating the flexible substrate form the rigid substrate and the inorganic thin film layer by laser lift-off process;
wherein the first surface of the flexible substrate is formed a plurality of patterning recesses which corresponding to the plurality of patterning projections.

8. The method of manufacture flexible OLED display panel according to claim 7, wherein longitudinal section of the recess is rectangular shape.

9. The method of manufacture flexible OLED display panel according to claim 7, wherein longitudinal section of the recess is trapezoid shape or counter trapezoid shape.

10. The method of manufacture flexible OLED display panel according to claim 7, wherein depth of the recess is equal to or smaller than half of thickness of the flexible substrate.

11. The method of manufacture flexible OLED display panel according to claim 7, wherein a plurality of patterning recesses is arranged on the first surface in array.

12. The method of manufacture flexible OLED display panel according to claim 7, wherein the OLED display unit comprises a TFT array layer, an anode layer, an organic light-emitting layer, a cathode layer and a packaged layer are formed on the second surface sequentially.

13. A display device, comprising a driver unit and a flexible OLED display panel, the driver unit provides driver signal to the flexible OLED display panel for displaying image on the flexible OLED display panel; the flexible OLD display panel comprising a flexible substrate and an OLED display unit formed on the flexible substrate; wherein the flexible substrate includes a first surface and a second surface corresponding to the first surface, the OLED display unit is formed on the second surface, a plurality of patterning recesses is formed on the first surface of the flexible substrate.

14. The display device according to claim 13, wherein longitudinal section of the recess is rectangular shape.

15. The display device according to claim 13, wherein longitudinal section of the recess is trapezoid shape or counter trapezoid shape.

16. The display device according to claim 13, wherein depth of the recess is equal to or smaller than half of thickness of the flexible substrate.

17. The display device according to claim 13, wherein a plurality of patterning recesses is arranged on the first surface in array.

18. The display device according to claim 13, wherein the OLED display unit comprises a TFT array layer, an anode layer, an organic light-emitting layer, a cathode layer and a packaged layer are formed on the second surface sequentially.
